(19) United States
(12) Patent Application Publication
(10) Pub. No.: US 2022/0139713 A1
(43) Pub. Date: May 5, 2022

(54) MOLYBDENUM DEPOSITION METHOD

(71) Applicant: ASM IP Holding B.V., Almere (NL)

(72) Inventors: Elina Färm, Helsinki (FI); Jan Willem Maes, Wilrijk (BE); Charles Dezelah, Helsinki (FI); Shinya Iwashita, Helsinki (FI)

(21) Appl. No.: 17/511,837

(22) Filed: Oct. 27, 2021

Related U.S. Application Data
(60) Provisional application No. 63/108,043, filed on Oct. 30, 2020.

(51) Int. Cl. H01L 21/285; C23C 16/18; C23C 16/455

(52) U.S. Cl. CPC H01L 21/28568; C23C 16/45553; C23C 16/18

(57) ABSTRACT

The current disclosure relates to methods of depositing molybdenum on a substrate. The disclosure further relates to a molybdenum layer, to a structure and to a device comprising a molybdenum layer. In the method, molybdenum is deposited on a substrate by a cyclical deposition process, and the method comprises providing a substrate in a reaction chamber, providing a molybdenum precursor to the reaction chamber in a vapor phase and providing a reactant to the reaction chamber in a vapor phase to form molybdenum on the substrate. The molybdenum precursor comprises a molybdenum atom and a hydrocarbon ligand, and the reactant comprises a hydrocarbon comprising two or more halogen atoms, and at least two halogen atoms are attached to different carbon atoms.

### CROSS-REFERENCE TO RELATED APPLICATIONS

This application claims priority to U.S. Provisional Patent Application Ser. No. 63/108,043 filed Oct. 30, 2020 titled MOLYBDENUM DEPOSITION METHOD, the disclosure of which is hereby incorporated by reference in its entirety.

### FIELD

The present disclosure relates to methods and apparatuses for the manufacture of semiconductor devices. More particularly, the disclosure relates to methods and systems for depositing molybdenum on a substrate, and layers comprising molybdenum.

### BACKGROUND

Semiconductor device fabrication processes generally use advanced deposition methods for forming metal and metal-containing layers. Molybdenum may have many of the advantages sought in the art. For example, it may be useful as a conductor in back end of line (BEOL) or mid end of line (MEOL) applications, or in buried power rail or in work function layer in logic applications and in word or bit line in advanced memory applications. However, the deposition of high quality molybdenum thin films by cyclical deposition methods remains challenging due to the electropositive nature of molybdenum and its tendency to form nitride or carbide phases. Thus there is need in the art for alternative or improved methods for depositing metallic molybdenum or molybdenum with low amounts of carbon and/or nitrogen.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY

This summary may introduce a selection of concepts in a simplified form, which may be described in further detail below. This summary is not intended to necessarily identify key features or essential features of the claimed subject matter, nor is it intended to be used to limit the scope of the claimed subject matter.

Various embodiments of the present disclosure relate to methods of depositing molybdenum.

In the current disclosure, methods of depositing molybdenum on a substrate by a cyclical deposition process are disclosed. The methods comprise providing a substrate in a reaction chamber, providing a molybdenum precursor to the reaction chamber in a vapor phase and providing a reactant to the reaction chamber in a vapor phase to form molybdenum on the substrate. The molybdenum precursor according to the current disclosure comprises a molybdenum atom and a hydrocarbon ligand, and the reactant comprises a halogenated hydrocarbon comprising two or more halogen atoms, at least two halogen atoms being attached to different carbon atoms.

The current disclosure further relates to a molybdenum layer produced by the method according to the current disclosure. Thus, a substrate is provided in a reaction chamber, a molybdenum precursor comprising a molybdenum atom and a hydrocarbon ligand is provided the reaction chamber in a vapor phase, and a reactant comprising a hydrocarbon comprising two or more halogen atoms, at least two halogen atoms being attached to different carbon atoms is provided to the reaction chamber to form molybdenum on the substrate.

In an additional aspect, the current disclosure relates to a structure comprising molybdenum deposited by a method according to the current disclosure. The molybdenum comprised in the structure may be deposited as a layer. In other words, it may be a molybdenum layer. As used herein, a “structure” can be or include a substrate as described herein. Structures can include one or more layers overlying the substrate, such as one or more layers formed by a method according to the current disclosure. The structure may be, for example, a via or a line in BEOL, or a contact or a local interconnect in MEOL. The structure may also be a work function layer in a gate electrode, or a buried power rail in logic applications, as well as a word line or a bit line in an advanced memory application.

In yet another aspect, the current disclosure relates to a semiconductor device comprising molybdenum deposited by a method according to the current disclosure. The device may be, for example, a gate electrode, a logic or a memory device.

In a further aspect, a deposition assembly is disclosed. The deposition assembly is constructed and arranged to deposit molybdenum on a substrate. The deposition assembly for depositing molybdenum on a substrate according to the current disclosure comprises one or more reaction chambers constructed and arranged to hold the substrate, and a precursor injector system constructed and arranged to provide a molybdenum precursor and/or a reactant into the reaction chamber in a vapor phase. The deposition assembly further comprises a precursor vessel constructed and arranged to contain and evaporate a molybdenum precursor comprising a molybdenum atom and a hydrocarbon ligand and a reactant vessel constructed and arranged to contain and evaporate a reactant comprising a halogenated hydrocarbon comprising two or more halogen atoms, at least two halogen atoms being attached to different carbon atoms. The deposition assembly is constructed and arranged to provide the molybdenum precursor and/or the reactant via the precursor injector system to the reaction chamber to deposit molybdenum on the substrate.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

### BRIEF DESCRIPTION OF DRAWINGS

The accompanying drawings, which are included to provide a further understanding of the disclosure and constitute a part of this specification, illustrate exemplary embodiments, and together with the description help to explain the principles of the disclosure. In the drawings

FIGS. 1A-1C exemplary embodiments of a method according to the current disclosure.

FIG. 2 depicts an exemplary structure comprising a molybdenum layer according to the current disclosure.

FIG. 3 presents a deposition apparatus according to the current disclosure in a schematic manner.

FIG. 4 depicts an exemplary device comprising molybdenum deposited according to the current disclosure.

FIG. 5, panels A to D depicts devices comprising molybdenum deposited according to the current disclosure.

FIG. 6 is a representation of a buried power rail comprising molybdenum deposited according to the current disclosure.

FIG. 7 depicts a device comprising a work function layer comprising molybdenum deposited according to the current disclosure.

FIG. 8 illustrates word lines in a 3D NAND comprising molybdenum deposited according to the current disclosure.

FIG. 9 displays an exemplary embodiment of word lines in a DRAM comprising molybdenum deposited according to the current disclosure.

### DETAILED DESCRIPTION

The description of exemplary embodiments of methods, structures, devices and apparatuses provided below is merely exemplary and is intended for purposes of illustration only. The following description is not intended to limit the scope of the disclosure or the claims. Moreover, recitation of multiple embodiments having indicated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

The current disclosure relates to a method of depositing molybdenum on a substrate. The method comprises providing a substrate in a reaction chamber, providing a molybdenum precursor in the reaction chamber in vapor phase and providing a reactant to the reaction chamber in a vapor phase to form molybdenum on the substrate. In the current disclosure, molybdenum may be deposited predominantly, or in some embodiments substantially completely or completely, as an elemental metal. By elemental molybdenum is herein meant molybdenum with an oxidation state of zero. Molybdenum deposited according to the current disclosure may comprise elemental molybdenum and other forms of molybdenum. For example, molybdenum deposited according to the current disclosure may have partly an oxidation state of 0, +2, +3, +4, +5 and/or +6. In some embodiments, at least 60% of molybdenum is deposited as elemental metal. In some embodiments, at least 80% or at least 90% of molybdenum is deposited as elemental metal. In some embodiments, at least 93% or 95% of molybdenum is deposited as elemental metal.

The terms “precursor” and “reactant” can refer to molecules (compounds or molecules comprising a single element) that participate in a chemical reaction that produces another compound. A precursor typically contains portions that are at least partly incorporated into the compound or element resulting from the chemical reaction in question. Such a resulting compound or element may be deposited on a substrate. A reactant may me an element or a compound that is not incorporated into the resulting compound or element to a significant extent.

As used herein, “a molybdenum precursor” includes a gas or a material that can become gaseous and that can be represented by a chemical formula that includes molybdenum. In some embodiments, molybdenum precursor is provided in a mixture of two or more compounds. In a mixture, the other compounds in addition to the molybdenum precursor may be inert compounds or elements. In some embodiments, molybdenum precursor is provided in a composition. Compositions suitable for use as composition can include a molybdenum compound and an effective amount of one or more stabilizing agents. Composition may be a solution or a gas in standard conditions.

In the methods according to the current disclosure, molybdenum precursor comprises a molybdenum atom and hydrocarbon ligand. In some embodiments, the molybdenum precursor comprises a metal-organic compound comprising molybdenum. Thus, the molybdenum precursor is a metal-organic precursor. By a metal-organic precursor is herein meant a molybdenum precursor comprising a molybdenum atom and a hydrocarbon ligand, wherein the molybdenum atom is not directly bonded to a carbon atom. In some embodiments, a metal-organic precursor comprises one molybdenum atom, which is not directly bonded with a carbon atom. In some embodiments, a metal-organic precursor comprises two or more molybdenum atoms, none of which is directly bonded to a carbon atom. In some embodiments, a metal-organic precursor comprises two or more metal atoms, wherein at least one metal atom is not directly bonded to a carbon atom.

In some embodiments, molybdenum precursor comprises an organometallic compound comprising molybdenum. Thus, the molybdenum precursor is an organometallic precursor. By an organometallic precursor is herein meant a molybdenum precursor comprising a molybdenum atom and a hydrocarbon ligand, wherein the molybdenum atom is directly bonded to a carbon atom. In embodiments in which an organometallic precursor comprises two or more metal atoms, all of the metal atoms are directly bonded with a carbon atom. In some embodiments, molybdenum precursor comprises only molybdenum, carbon and hydrogen. In other words, molybdenum precursor does not contain oxygen, nitrogen or other additional elements. In some embodiments, molybdenum precursor comprises at least two hydrocarbon ligands. In some embodiments, molybdenum precursor comprises at least three hydrocarbon ligands. In some embodiments, molybdenum precursor comprises four hydrocarbon ligands. In some embodiments, molybdenum precursor comprises a hydrocarbon ligand and a hydride ligand. In some embodiments, molybdenum precursor comprises a hydrocarbon ligand and two or more hydride ligands. In some embodiments, molybdenum precursor comprises two hydrocarbon ligands and two hydride ligands.

In some embodiments, molybdenum precursor comprises cyclic portions. For example, the molybdenum precursor may comprise one or more benzene rings. In some embodiments, the molybdenum precursor comprises two benzene rings. One or both benzene rings may comprise hydrocarbon substituents. In some embodiments, each benzene ring of the molybdenum precursor comprises an alkyl substituent. An alkyl substituent may be a methyl group, an ethyl group, or a linear or branched alkyl group comprising three, four, five or six carbon atoms. For example, the alkyl substituent of the benzene ring may be an n-propyl group or an iso-propyl group. Further, the alkyl substituent may be an n-, iso-, tert- or sec-form of a butyl, pentyl or hexyl moiety. In some embodiments, the molybdenum precursor comprises, consist essentially of, or consist of bis(ethylbenzene)molybdenum.

In some embodiments, molybdenum precursor comprises a cyclopentadienyl (Cp) ligand. For example, the molybdenum precursor may comprise, consist essentially of, or consist of MoCp₂Cl₂ or MoCp₂H₂, Mo(iPrCp)₂Cl₂, Mo(iPrCp)₂H₂, Mo(EtCp)₂H₂.

In some embodiments, the molybdenum precursor comprises a carbonyl group-containing ligand. For example, the molybdenum precursor may comprise, consist essentially of, or consist of Mo(CO)₆, Mo(1,3,5-cycloheptatriene)(CO)₃. Additionally, in some embodiments, the molybdenum precursor comprises a nitrosyl group-containing ligand. For example, the molybdenum precursor may comprise, consist essentially of, or consist of MoCp(CO)₂(NO).

In the methods according to the current disclosure, reactant comprises a halogenated hydrocarbon comprising two or more halogen atoms. At least two halogen atoms of the reactant are attached to different carbon atoms. The reactant comprises a hydrocarbon containing at least two carbon atoms attached to each other. The reactant may comprise also three carbon atoms. Further, the reactant may comprise four, five or six carbon atoms. The reactant may comprise a linear, branched, cyclical and/or aromatic carbon chain. For example, the reactant may comprise a halogenated ethane, propane, 2-methylpropane, 2,2-dimethylpropane (neopentane), n-butane, 2-methylbutane, 2,2-dimethylbutane, n-pentane, 2-methylpantane, 3-methylpentane or an n-hexane.

The reactant comprises two or more halogen atoms, and at least two halogen atoms are attached to different carbon atoms. The halogen atoms may be the same halogen, for example bromine, iodine, fluorine or chlorine. Alternatively, the halogens may be different halogens, such as iodine and bromine, bromine and chlorine, chlorine and iodine. The reactant may comprise two halogen atoms attached to different carbon atoms. The reactant may comprise three halogen atoms, each attached to a different carbon atom. The reactant may comprise four halogen atoms, each attached to a different carbon atom. Alternatively, in embodiments where the reactant comprises three, four or more halogen atoms, some carbon atoms may be attached to two or three halogen atoms.

In some embodiments, the two halogen atoms in the reactant are attached to adjacent carbon atoms of the hydrocarbon. Thus, the reactant may comprise two adjacent carbon atoms, each having at least one halogen substituent. In some embodiments, each of the adjacent carbon atoms has only one halogen substituent. Alternatively, one or both of the carbon atoms being attached to a halogen, may have two halogen atoms attached to it. Embodiments may be envisaged in which one or both of the carbon atoms being attached to a halogen, have three halogen atoms attached to it. The location of said two carbon atoms in a carbon chain may vary. In some embodiments, they are at the end of a carbon chain, but in some embodiments they are located away from the end of a carbon chain. As is evident to those skilled in the art, the position of a given carbon atom in a carbon chain limits the number of potential substituents available.

For example, in embodiments, where the reactant comprises two carbon atoms, at least one halogen atom is attached to each carbon. If a two-carbon reactant comprises two halogen atoms, then each of them is attached to a different carbon atom. In embodiments where the reactant comprises two carbon atoms and three halogens, one of the carbon atoms is doubly substituted with a halogen. In embodiments where the reactant comprises two carbon atoms and four halogens, both of the carbon atoms may be doubly substituted with a halogen. Alternatively, one carbon atom may have one halogen substituent, whereas the second may have three.

Similarly, in embodiments where the reactant comprises three carbon atoms and two halogen atoms, each halogen atom is attached to a different carbon atom. Thus one carbon atom does not have a halogen atom attached to it. Two halogen atoms may be attached to neighboring carbon atoms (i.e. carbon atoms adjacent to each other in a carbon chain). Alternatively, there may be one carbon atom between the halogenated carbon atoms. For example, reactant may comprise, consist essentially of, or consist of 1,2-dihalopropane or 1,3-dihalopropane, such as 1,2-dichloropropane, 1,3-dichloropropane, 1,2-diiodopropane or 1,3-diiodopropane, 1,2-difluoropropane or 1,3-difluoropropane.

In embodiments where the reactant comprises three carbon atoms and three halogen atoms, each carbon atom may have a halogen atom attached to it. Alternatively, any one of the three carbon atoms may have two halogen atoms attached to it, and one carbon atom—either at the end of the carbon chain or in the middle of it—may be without a halogen. The doubly substituted carbon atom may be at the end of the carbon chain or in the middle of it. As a further alternative, in some embodiments, a three-carbon reactant may contain four halogen atoms. In such embodiments, each carbon may have a halogen atom attached to it, and one carbon—either at the end of the carbon chain or in the middle of it—may have an additional halogen atom attached to it. As a still further alternative, two of the carbons may have two halogen atoms attached to it, whereas one carbon atom—either at the end of the carbon chain or in the middle of it—may be without a halogen. In some embodiments, the reactant comprises 1,2-dihaloalkane or 1,2-dihaloalkene or 1,2-dihaloalkyne or 1,2-dihaloarene, where the halogens are attached to adjacent carbon atoms.

In some embodiments, a reactant has a general formula XₐR_{b}C—(CX_{c}R″_{d})ₙ—CXₐR′_{b}, wherein X is halogen, R, R′ and R″ are independently H or an alkyl group, a and b are independently 1 or 2, so that for each carbon atom a+b=3, n is 0, 1, 2, 3, 4 or 5, and wherein c and d are independently 0, 1 or 2, so that for each carbon atom c+d=2.

In some embodiments, a reactant has a general formula XₐR_{b}C—CXₐR′_{b}, wherein X is halogen, R and R′ are independently H or an alkyl group, a and b are independently 1, 2 or 3 so that for each carbon atom a+b=3.

In embodiments in which the reactant comprises four carbon, there may be two, three, four, five or six halogen substituents attached to the carbons. For example, the reactant may have a formula CH₃—CXH—CH₂—CXH₂, CH₃—CH₂—CXH—CXH₂, CH₃—CXH—CXH—CH₃ or H₂CX—CH₂—CH₂—CXH₂. In embodiments where the four-carbon halogen comprises three carbons, the reactant may have a formula such as H₂CX—CXH—CH₂—CXH₂, H₂CX—CXH—CXH—CH₃, HCX₂—CXH—CH₂—CH₃, HCX₂—CH₂—CXH—CH₃ or HCX₂—CH₂—CH₂—CXH₂ or CH₃—CXH—CX₂—CH₃. In the formulas, X represents a halogen. Examples of such reactants are 1,2-dihalobutane, 1,3-dihalobutane and 1,4-dihalobutane.

A cyclic or an aromatic reactant may be used on some embodiments. In some embodiments, reactant comprises a cyclic or an aromatic compound. A reactant may comprise a di-halogenated benzene ring. The benzene ring may comprise two or more halogens. The benzene ring may contain additional substituents, such as one or more alkyl groups as described above. A reactant may comprise, consist essentially of, or consist of a di-halogenated benzene, such as 1,2-dibromobenzene, 1,2-diiodobenzene or 1,2-dichloroobenzene. The di-halogenated benzene, may also be a 1,3-dihalogenated or a 1,4-dihalogenated benzene. Further, a tri-halogenated benzene, such as 1,2,3- or 1,2,4-halogenated benzene is possible. An aromatic reactant may comprise four, five or six halogens. Cyclical reactants may comprise a cyclopentane or a cyclohexane, for example. A cyclical reactant may comprise two or more halogens. For example, a cyclohexane may contain up to twelve halogens, which may be the same or different. The halogens may be situated in cis- or trans-configuration. The halogens in a cyclohexane may be located in carbon positions 1 and 2, 1 and 3, 1 and 4, or 1, 2, 3 or 1,2,4. Examples of cyclic reactants are 1,2-diiodocyclohexane, 1,3-diiodocyclohexane, 1,4-diiodocyclohexane, 1,2-dibromocyclohexane, 1,3-dibromocyclohexane, 1,4-dibromocyclohexane, 1,2-difluorocyclohexane, 1,3-difluorocyclohexane, 1,4-difluorocyclohexane

In some embodiments, the reactant has a general formula XₐR_{b}C—CXₐR′_{b}, wherein X is halogen, R and R′ are independently H or an alkyl group, a and b are independently 1 or 2, so that for each carbon atom a+b=3. In some embodiments, X is iodine. In some embodiments, X is bromine. In some embodiments, X is chlorine. In some embodiments, a is 1 for both carbon atoms. In some embodiments a is 1 for one carbon atom, and 2 for the other carbon atom. In some embodiments, R and R′ are both H.

In some embodiments, molybdenum may be deposited on a substrate as a layer. In such embodiments, molybdenum forms a molybdenum layer. As used herein, a “molybdenum layer” can be a material layer that contains molybdenum. As used herein, the term “layer” and/or “film” can refer to any continuous or non-continuous structure and material, such as material deposited by the methods disclosed herein. For example, layer and/or film can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous. A seed layer may be a non-continuous layer serving to increase the rate of nucleation of another material. However, the seed layer may also be substantially or completely continuous.

Without limiting the current disclosure to any specific theory, in some embodiments it may be possible to produce molybdenum layers with low resistivity. The resistivity of a molybdenum layer according to the current disclosure may be from about 5 μΩcm to about 300 μΩcm, or from about 5 μΩcm to about 100 μΩcm, or from about 5 μΩcm to about 50 μΩcm such as about 10 μΩcm, 15 μΩcm, 20 μΩcm or 30 μΩcm. In other embodiments, the resistivity of a molybdenum layer may be about 50 μΩcm, 100 μΩcm, 150 μΩcm or 200 μΩcm.

The molybdenum may be at least partly in elemental form. Thus, the oxidation state of molybdenum may be zero. A molybdenum layer can include additional elements, such as nitrogen, carbon and/or oxygen. Other additional or alternative elements are possible. In some embodiments, the molybdenum layer may comprise significant proportions of other elements than molybdenum. However, in some embodiments, molybdenum layer may contain substantially only molybdenum. Thus, molybdenum layer may comprise, consist essentially of, or consist of molybdenum. In some embodiments, the molybdenum layer may be a seed layer. A seed layer may be used to enhance the deposition of another layer.

In some embodiments, a molybdenum layer may comprise, for example, about 60 to about 99 atomic percentage (at. %) molybdenum, or about 75 to about 99 at. % molybdenum, or about 75 to about 95 at. % molybdenum, or about 80 to about 95 at. % molybdenum. A molybdenum layer deposited by a method according to the current disclosure may comprise, for example about 80 at. %, about 83 at. %, about 85 at. %, about 87 at. %, about 90 at. %, about 95 at. %, about 97 at. % or about 99 at. % molybdenum. In some embodiments, a molybdenum layer may consist essentially of, or consist of molybdenum. In some embodiments, molybdenum layer may consist essentially of, or consist of molybdenum. Layer consisting of molybdenum may include an acceptable amount of impurities, such as oxygen, carbon, chlorine or other halogen, and/or hydrogen that may originate from one or more precursors used to deposit the molybdenum layer.

In some embodiments, the molybdenum layer may comprise less than about 30 at. %, less than about 20 at. %, less than about 10 at. %, less than about 8 at. %, less than about 7 at. %, less than about 5 at. %, or less than about 2 at. % oxygen. In some embodiments, the molybdenum layer may comprise less than about 20 at. %, less than about 15 at. %, less than about 10 at. %, less than about 8 at. %, less than about 6 at. %, less than about 5 at. %, less than 4.5 at. %, or less than about 3 at. % carbon.

The substrate may be any underlying material or materials that can be used to form, or upon which, a structure, a device, a circuit, or a layer can be formed. A substrate can include a bulk material, such as silicon (e.g., single-crystal silicon), other Group IV materials, such as germanium, or other semiconductor materials, such as a Group II-VI or Group III-V semiconductor materials, and can include one or more layers overlying or underlying the bulk material. Further, the substrate can include various features, such as recesses, protrusions, and the like formed within or on at least a portion of a layer of the substrate. For example, a substrate can include bulk semiconductor material and an insulating or dielectric material layer overlying at least a portion of the bulk semiconductor material. Substrate may include nitrides, for example TiN, oxides, insulating materials, dielectric materials, conductive materials, metals, such as such as tungsten, ruthenium, molybdenum, cobalt, aluminum or copper, or metallic materials, crystalline materials, epitaxial, heteroepitaxial, and/or single crystal materials. In some embodiments of the current disclosure, the substrate comprises silicon. The substrate may comprise other materials, as described above, in addition to silicon. The other materials may form layers.

The method of depositing molybdenum according to the current disclosure comprises providing a substrate in a reaction chamber. In other words, a substrate is brought into space where the deposition conditions can be controlled. The reaction chamber may be part of a cluster tool in which different processes are performed to form an integrated circuit. In some embodiments, the reaction chamber may be a flow-type reactor, such as a cross-flow reactor. In some embodiments, the reaction chamber may be a showerhead reactor. In some embodiments, the reaction chamber may be a space-divided reactor. In some embodiments, the reaction chamber may be single wafer ALD reactor. In some embodiments, the reaction chamber may be a high-volume manufacturing single wafer ALD reactor. In some embodiments, the reaction chamber may be a batch reactor for manufacturing multiple substrates simultaneously.

In the method according to the current disclosure, the molybdenum precursor may be in vapor phase when it is in a reaction chamber. The molybdenum precursor may be partially gaseous or liquid, or even solid at some points in time prior to being provided in the reaction chamber. In other words, a molybdenum precursor may be solid, liquid or gaseous, for example, in a precursor vessel or other receptacle before delivery in a reaction chamber. Various means of bringing the precursor in to gas phase can be applied when delivery into the reaction chamber is performed. Such means may include, for example, heaters, vaporizers, gas flow or applying lowered pressure, or any combination thereof. Thus, the method according to the current disclosure may comprise heating the molybdenum precursor prior to providing it to the reaction chamber. In some embodiments, molybdenum precursor is heated to at least 100° C., or to at least 110° C., or to at least 120° C. or to at least 130° C. or to at least 140° C. in the vessel. Also the injector system may be heated to improve the vapor phase delivery of the molybdenum precursor to the reaction chamber.

In this disclosure, “gas” can include material that is a gas at normal temperature and pressure (NTP), a vaporized solid and/or a vaporized liquid, and can be constituted by a single gas or a mixture of gases, depending on the context. Molybdenum precursor may be provided to the reaction chamber in gas phase. The term “inert gas” can refer to a gas that does not take part in a chemical reaction and/or does not become a part of a layer to an appreciable extent. Exemplary inert gases include He and Ar and any combination thereof. In some cases, molecular nitrogen and/or hydrogen can be an inert gas. A gas other than a process gas, i.e., a gas introduced without passing through a precursor injector system, other gas distribution device, or the like, can be used for, e.g., sealing the reaction space, and can include a seal gas.

In the method according to the current disclosure, the reactant may be contacted with the substrate comprising a chemisorbed molybdenum precursor. The conversion of a molybdenum precursor to molybdenum may take place at the substrate surface. In some embodiments, the conversion may take place at least partially in the gas phase.

In the current disclosure, the deposition process may comprise a cyclical deposition process, such as an atomic layer deposition (ALD) process or a cyclical chemical vapor deposition (VCD) process. The term “cyclical deposition process” can refer to the sequential introduction of precursor(s) and/or reactant(s) into a reaction chamber to deposit material, such as molybdenum, on a substrate. Cyclic deposition includes processing techniques such as atomic layer deposition (ALD), cyclical chemical vapor deposition (cyclical CVD), and hybrid cyclical deposition processes that include an ALD component and a cyclical CVD component. The process may comprise a purge between providing precursors or between providing a precursor and a reactant in the reaction chamber.

The process may comprise one or more cyclical phases. In some embodiments, the process comprises or one or more acyclical phases. In some embodiments, the deposition process comprises the continuous flow of at least one precursor. In some embodiments, a reactant may be continuously provided in the reaction chamber. In such an embodiment, the process comprises a continuous flow of a reactant.

The term “atomic layer deposition” (ALD) can refer to a vapor deposition process in which deposition cycles, such as a plurality of consecutive deposition cycles, are conducted in a reaction chamber. The term atomic layer deposition, as used herein, is also meant to include processes designated by related terms, such as chemical vapor atomic layer deposition, when performed with alternating pulses of precursor(s)/reactant(s), and optional purge gas(es). Generally, for ALD processes, during each cycle, a precursor is introduced to a reaction chamber and is chemisorbed to a deposition surface (e.g., a substrate surface that may include a previously deposited material from a previous ALD cycle or other material), forming about a monolayer or sub-monolayer of material that does not readily react with additional precursor (i.e., a self-limiting reaction). Thereafter, in some cases, a reactant (e.g., another precursor or a reaction gas) may subsequently be introduced into the process chamber for use in converting the chemisorbed precursor to the desired material on the deposition surface. The reactant can be capable of further reaction with the precursor. Purging may be utilized during one or more cycles, e.g., during each stage of each cycle, to remove any excess precursor from the process chamber and/or remove any excess reactant and/or reaction byproducts from the reaction chamber.

CVD type processes typically involve gas phase reactions between two or more reactants. The precursor(s) and reactant(s) can be provided simultaneously to the reaction space or substrate, or in partially or completely separated pulses. The substrate and/or reaction space can be heated to promote the reaction between the gaseous reactants. In some embodiments the precursor(s) and reactant(s) are provided until a layer having a desired thickness is deposited. In some embodiments, cyclical CVD processes can be used with multiple cycles to deposit a thin film having a desired thickness. In cyclical CVD processes, the reactants may be provided to the reaction chamber in pulses that do not overlap, or that partially or completely overlap.

In some embodiments, molybdenum precursor, reactant or both are provided to the reaction chamber in pulses. The length of a molybdenum precursor pulse or a reactant pulse may be, for example, from about 0.01 s to about 60 s, for example from about 0.01 s to about 5 s, or from about 1 s to about 20 s, or from about 0.5 s to about 10 s, or from about 5 s to about 15 s, or from about 10 s to about 30 s, or from about 10 s to about 60 s, or from about 20 s to about 60 s. The length of a molybdenum precursor or a reactant pulse may be, for example 0.03 s, 0.1 s, 0.5 s, 1 s, 1.5 s, 2 s, 2.5 s, 3 s, 4 s, 5 s, 8 s, 10 s, 12 s, 15 s, 25 s, 30 s, 40 s, 50 s or 60 s. In some embodiments, molybdenum precursor pulse time may be at least 5 seconds, or at least 10 seconds, or at least 20 seconds, or at least 30 seconds. In some embodiments, molybdenum precursor pulse time may be at most 5 seconds, or at most 10 seconds or at most 20 seconds, or at most 30 seconds. In some embodiments, reactant pulse time may be at least 15 seconds, or at least 30 seconds, or at least 45 seconds, or at least 60 seconds. In some embodiments, reactant pulse time may be at most 15 seconds, or at most 30 seconds or at most 45 seconds, or at most 60 seconds.

The pulse times for molybdenum precursor and reactant vary independently according to process in question. The selection of an appropriate pulse time may depend on the substrate topology. For higher aspect ratio structures, longer pulse times may be needed to obtain sufficient surface saturation in different areas of a high aspect ratio structure. Also the selected molybdenum precursor and reactant chemistries may influence suitable pulsing times. For process optimization purposes, shorter pulse times might be preferred as long as appropriate layer properties can be achieved. In some embodiments, molybdenum precursor pulse time is longer than reactant pulse time. In some embodiments, reactant pulse time is longer than molybdenum precursor pulse time. In some embodiments, molybdenum precursor pulse time is same as reactant pulse time.

In some embodiments, molybdenum precursor may be pulsed more than one time, for example two, three or four times, before a reactant is pulsed to the reaction chamber. Similarly, there may be more than one pulse, such as two, three or four pulses, of a reactant before molybdenum precursor is pulsed (i.e. provided) to the reaction chamber.

In some embodiments, the method comprises removing excess molybdenum precursor from the reaction chamber by an inert gas prior to providing the reactant in the reaction chamber. In some embodiments, the reaction chamber is purged between providing a molybdenum precursor in a reaction chamber and providing a reactant in the reaction chamber. In some embodiments, there is a purge between every pulse. Thus, the reaction chamber may be purged also between two pulses of the same chemistry, such as a molybdenum precursor or a reactant.

As used herein, the term “purge” may refer to a procedure in which vapor phase precursors and/or vapor phase byproducts are removed from the substrate surface for example by evacuating the reaction chamber with a vacuum pump and/or by replacing the gas inside a reaction chamber with an inert or substantially inert gas such as argon or nitrogen. Purging may be effected between two pulses of gases which react with each other. However, purging may be effected between two pulses of gases that do not react with each other. For example, a purge, or purging may be provided between pulses of two precursors or between a precursor and a reactant. Purging may avoid or at least reduce gas-phase interactions between the two gases reacting with each other. It shall be understood that a purge can be effected either in time or in space, or both. For example in the case of temporal purges, a purge can be used e.g. in the temporal sequence of providing a first precursor to a reactor chamber, providing a purge gas to the reactor chamber, and providing a second precursor to the reactor chamber, wherein the substrate on which a layer is deposited does not move. For example in the case of spatial purges, a purge an take the following form: moving a substrate from a first location to which a first precursor is continually supplied, through a purge gas curtain, to a second location to which a second precursor is continually supplied. Purging times may be, for example, from about 0.01 seconds to about 20 seconds, from about 1 s to about 20 s, or from about 0.5 s to about 10 s, or between about 1 s and about 7 seconds, such as 5 s, 6 s or 8 s. However, other purge times can be utilized if necessary, such as where highly conformal step coverage over extremely high aspect ratio structures or other structures with complex surface morphology is needed, or in specific reactor types, such as a batch reactor, may be used.

In some embodiments, the method according to the current disclosure comprises a thermal deposition process. In thermal deposition, the chemical reactions are promoted by increased temperature relevant to ambient temperature. Generally, temperature increase provides the energy needed for the formation of molybdenum in the absence of other external energy sources, such as plasma, radicals, or other forms of radiation. In some embodiments, the method according to the current disclosure is a plasma-enhanced deposition method, for example PEALD or PECVD.

A flow rate of the molybdenum precursor or a reactant (i.e. molybdenum precursor and reactant flow rate, respectively) may vary from about 5 sccm to about 20 slm. A flow rate of the molybdenum precursor or the reactant may be less than 3,000 sccm, or less than 2,000 sccm, or less than 1,000 sccm, or less than 600 sccm. In some embodiments, a molybdenum precursor or reactant flow rate may be lower, for example, from about 5 sccm to about 50 sccm, or from about 10 sccm to about 500 sccm. For example, a flow rate of the molybdenum precursor or the reactant may be 500 sccm, 600 sccm, 700 sccm, 800 sccm or 900 sccm, 1,000 sccm or 1,100 sccm. In some embodiments, higher flow rates may be utilized. For example, a molybdenum precursor or a reactant flow rate may be 5 slm or higher. In some embodiments, a molybdenum precursor or reactant flow rate may be 10 slm, 12 slm or 15 slm or 20 slm.

In some embodiments, molybdenum may be deposited at a temperature from about 150° C. to about 400° C. For example, molybdenum may be deposited at a temperature from about 200° C. to about 400° C., or at a temperature from about 250° C. to about 350° C. In some embodiments of the current disclosure, molybdenum may be deposited at a temperature from about 260° C. to about 330° C., or at a temperature from about 270° C. to about 330° C. In some embodiments, molybdenum may be deposited at a temperature from about 150° C. to about 200° C., or at a temperature from about 300° C. to about 400° C., or at a temperature from about 280° C. to about 320° C. For example, molybdenum may be deposited at a temperature of about 210° C. or about 225° C. or about 285° C., or about 290° C., or about 310° C., or about 315° C. or about 325° C., or about 375° C., or about 380° C., or about 385° C., or about 390° C.

A pressure in a reaction chamber may be selected independently for different process stages. In some embodiments, a first pressure may be used during molybdenum precursor pulse, and a second pressure may be used during reactant pulse. A third or a further pressure may be used during purging or other process stages. In some embodiments, a pressure within the reaction chamber during the deposition process is less than 760 Torr, or wherein a pressure within the reaction chamber during the deposition process is between 0.2 Torr and 760 Torr, or between 1 Torr and 100 Torr, or between 1 Torr and 10 Torr. In some embodiments, a pressure within the reaction chamber during the deposition process is less than about 0.001 Torr, less than 0.01 Torr, less than 0.1 Torr, less than 1 Torr, less than 10 Torr, less than 50 Torr, less than 100 Torr or less than 300 Torr. In some embodiments, a pressure within the reaction chamber during at least a part of the method according to the current disclosure is less than about 0.001 Torr, less than 0.01 Torr, less than 0.1 Torr, less than 1 Torr, less than 10 Torr or less than 50 Torr, less than 100 Torr or less than 300 Torr. For example, in some embodiments, a first pressure may be about 0.1 Torr, about 0.5 Torr, about 1 Torr, about 5 Torr, about 10 Torr, about 20 Torr or about 50 Torr. In some embodiments, a second pressure is about 0.1 Torr, about 0.5 Torr, about 1 Torr, about 5 Torr, about 10 Torr, about 20 Torr or about 50 Torr.

The disclosure is further explained by the following exemplary embodiments depicted in the drawings. The illustrations presented herein are not meant to be actual views of any particular material, structure, or device, but are merely schematic representations to describe embodiments of the current disclosure. It will be appreciated that elements in the figures are illustrated for simplicity and clarity and have not necessarily been drawn to scale. For example, the dimensions of some of the elements in the figures may be exaggerated relative to other elements to help improve the understanding of illustrated embodiments of the present disclosure. The structures and devices depicted in the drawings may contain additional elements and details, which may be omitted for clarity.

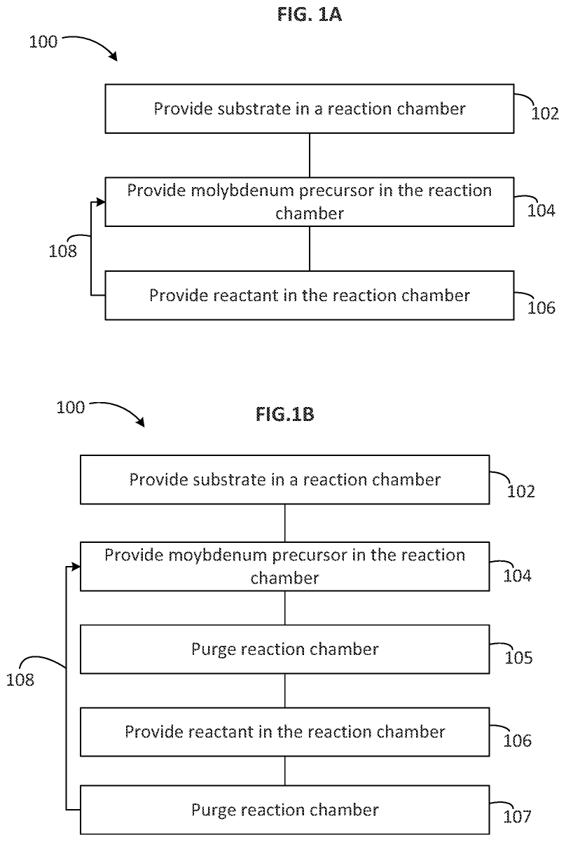

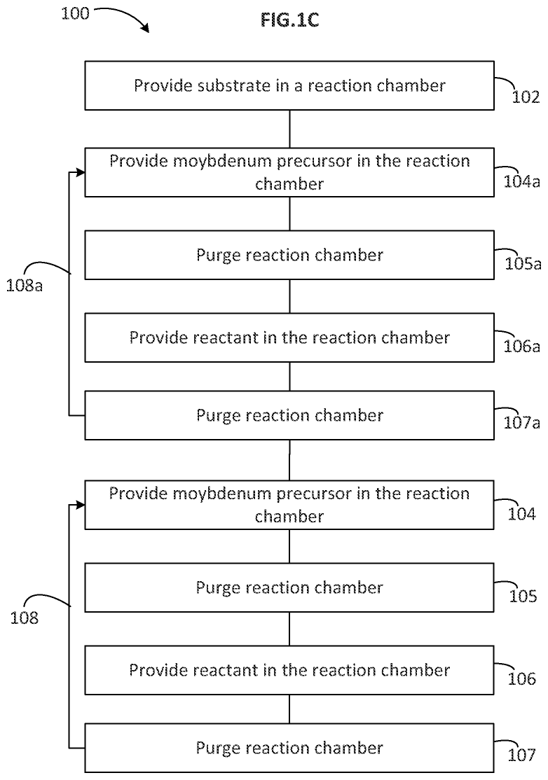

FIGS. 1A-1C illustrates an exemplary embodiment of a method 100 according to the current disclosure. Method 100 may be used to form a layer comprising molybdenum, i.e. a molybdenum layer. The molybdenum layer can be used during a formation of a structure or a device, such as a structure or a device described herein. However, unless otherwise noted, methods are not limited to such applications.

During stage 102, a substrate is provided into a reaction chamber of a reactor. The reaction chamber can form part of an atomic layer deposition (ALD) reactor. The reactor may be a single wafer reactor. Alternatively, the reactor may be a batch reactor. Various phases of method 100 can be performed within a single reaction chamber or they can be performed in multiple reactor chambers, such as reaction chambers of a cluster tool. In some embodiments, the method 100 is performed in a single reaction chamber of a cluster tool, but other, preceding or subsequent, manufacturing stages of the structure or device are performed in additional reaction chambers of the same cluster tool. Optionally, a reactor including the reaction chamber can be provided with a heater to activate the reactions by elevating the temperature of one or more of the substrate and/or the reactants and/or precursors.

During stage 102, the substrate can be brought to a desired temperature and pressure for providing molybdenum precursor in the reaction chamber 104 and/or for providing reactant in the reaction chamber 106. A temperature (e.g. of a substrate or a substrate support) within a reaction chamber can be, for example, from about 150° C. to about 400° C., or from about 250° C. to about 350° C. As a further example, a temperature within a reaction chamber can be from about 275° C. to about 325° C., or from about 280° C. to about 320° C. Exemplary temperatures within the reaction chamber may be 225° C., 250° C., 275° C., 285° C., 300° C., 310° C., 320° C., and 330° C.

A pressure within the reaction chamber can be less than 760 Torr, for example 400 Torr, 100 Torr, 50 Torr or 20 Torr, 5 Torr, Torr or 0.1 Torr. Different pressure may be used for different process stages.

Molybdenum precursor is provided in the reaction chamber containing the substrate 104. Without limiting the current disclosure to any specific theory, molybdenum precursor may chemisorb on the substrate during providing molybdenum precursor in the reaction chamber. The duration of providing molybdenum precursor in the reaction chamber (molybdenum precursor pulse time) may be, for example, 0.01 s, 0.5 s, 1 s, 1.5 s, 2 s, 2.5 s, 3 s, 3.5 s, 4 s, 4.5 s or 5 s. In some embodiments, the duration of providing molybdenum precursor in the reaction chamber (molybdenum precursor pulse time) is may be more than 5 s or more than 10 s or about 20 s.

When reactant is provided in the reaction chamber 106, it may react with the chemisorbed molybdenum precursor, or its derivate species, to form molybdenum. The duration of providing reactant in the reaction chamber (reactant pulse time) may be, for example 0.5 s, 1 s, 2 s, 3 s, 3.5 s, 4 s, 5 s, 6 s, 7 s, 8 s, 10 s, 12 s, 15 s, 30 s, 40 s, 50 s or 60 s. In some embodiments, the duration of providing reactant in the reaction chamber is be less than 15 s or less than 10 s or about 3 s.

In some embodiments, molybdenum precursor may be heated before providing it into the reaction chamber. In some embodiments, the reactant may be heated before providing it to the reaction chamber. In some embodiments, the reactant may kept in ambient temperature before providing it to the reaction chamber.

Stages 104 and 106, performed in any order, may form a deposition cycle, resulting in the deposition of molybdenum. In some embodiments, the two stages of molybdenum deposition, namely providing the molybdenum precursor and the reactant in the reaction chamber (104 and 106), may be repeated (loop 108). Such embodiments contain several deposition cycles. The thickness of the deposited molybdenum may be regulating by adjusting the number of deposition cycles. The deposition cycle (loop 108) may be repeated until a desired molybdenum thickness is achieved. For example about 50, 100, 150, 200, 250, 300, 400, 500, 600, 700, 800, 1,200 or 1,500 deposition cycles may be performed.

The amount of molybdenum deposited during one cycle (growth per cycle) varies depending on the process conditions, and may be, for example, from about 0.3 Å/cycle to about 4.5 Å/cycle, such as from about 0.5 Å/cycle to about 3.5 Å/cycle or from about 1.2 Å/cycle to about 3.0 Å/cycle. For example, the growth rate may be about 1.0 Å/cycle, 1.2 Å/cycle, 1.4. Å/cycle, 1.6 Å/cycle, 1.8 Å/cycle, 2 Å/cycle, 2.2 Å/cycle, 2.4 Å/cycle. Depending on the deposition conditions, deposition cycle numbers etc., molybdenum layers of variable thickness may be deposited. For example, molybdenum or molybdenum-containing layer may have a thickness between approximately 0.2 nm and 60 nm, or between about 1 nm and 50 nm, or between about 0.5 nm and 25 nm, or between about 1 nm and 50 nm, or between about 10 nm and 60 nm. A molybdenum layer may have a thickness of, for example, approximately 0.2 nm, 0.3 nm, 0.5 nm, 1 nm, 1.5 nm, 2 nm, 2.5 nm, 3 nm, 3.5 nm, 4 nm, 4.5 nm, 5 nm, 6 nm, 8 nm, 10 nm, 15 nm, 20 nm, 25 nm, 30 nm, 35 nm, 40 nm, 50 nm, 70 nm, 85 nm or 100 nm. The desired thickness may be selected according to the application in question.

Molybdenum precursor and reactant may be provided in the reaction chamber in separate stages (104 and 106). FIG. 1B illustrates an embodiment according to the current disclosure, where stages 104 and 106 are separate by purge stages 105 and 107. In such embodiments, a deposition cycle comprises one or more purge stages 103, 105. During purge stages, precursor and/or reactant can be temporally separated from each other by inert gases, such as argon (Ar), nitrogen (N₂) or helium (He) and/or a vacuum pressure. The separation of molybdenum precursor and reactant may alternatively be spatial.

Purging the reaction chamber 103, 105 may prevent or mitigate gas-phase reactions between a molybdenum precursor and a reactant, and enable possible self-saturating surface reactions. Surplus chemicals and reaction byproducts, if any, may be removed from the substrate surface, such as by purging the reaction chamber or by moving the substrate, before the substrate is contacted with the next reactive chemical. In some embodiments, however, the substrate may be moved to separately contact a molybdenum precursor and a reactant. Because in some embodiments, the reactions may self-saturate, strict temperature control of the substrates and precise dosage control of the precursors may not be required. However, the substrate temperature is preferably such that an incident gas species does not condense into monolayers or multimonolayers nor thermally decompose on the surface.

When performing the method 100, molybdenum is deposited onto the substrate. The deposition process may be a cyclical deposition process, and may include cyclical CVD, ALD, or a hybrid cyclical CVD/ALD process. For example, in some embodiments, the growth rate of a particular ALD process may be low compared with a CVD process. One approach to increase the growth rate may be that of operating at a higher deposition temperature than that typically employed in an ALD process, resulting in some portion of a chemical vapor deposition process, but still taking advantage of the sequential introduction of a molybdenum precursor and a reactant. Such a process may be referred to as cyclical CVD. In some embodiments, a cyclical CVD process may comprise the introduction of two or more precursors into the reaction chamber, wherein there may be a time period of overlap between the two or more precursors in the reaction chamber resulting in both an ALD component of the deposition and a CVD component of the deposition. This is referred to as a hybrid process. In accordance with further examples, a cyclical deposition process may comprise the continuous flow of one reactant or precursor and the periodic pulsing of the other chemical component into the reaction chamber. The temperature and/or pressure within a reaction chamber during stage 104 can be the same or similar to any of the pressures and temperatures noted above in connection with stage 102.

In some embodiments, the molybdenum precursor is brought into contact with a substrate surface 104, excess molybdenum precursor is partially or substantially completely removed by an inert gas or vacuum 105, and reactant is brought into contact with the substrate surface comprising molybdenum precursor. Molybdenum precursor may be brought in to contact with the substrate surface in one or more pulses 104. In other words, pulsing of the molybdenum precursor 104 may be repeated. The molybdenum precursor on the substrate surface may react with the reactant to form molybdenum on the substrate surface. Also pulsing of the reactant 106 may be repeated. In some embodiments, reactant may be provided in the reaction chamber first 106. Thereafter, the reaction chamber may be purged 105 and molybdenum precursor provided in the reaction chamber in one or more pulses 104.

For example, if a molybdenum layer is deposited at a temperature of between 270 to 310° C., and the deposition cycle (providing molybdenum precursor and reactant, separated by purging) is repeated between 100 and 200 times, it may be possible to obtain a molybdenum layer with a thickness between approximately 10 nm and 40 nm, for example 20 nm or 30 nm.

In some embodiments, molybdenum layer according to the current disclosure may have a resistivity of from about 5 μΩcm to about 300 μΩcm. For example, the resistivity of a molybdenum layer according to the current disclosure may be 10 μΩcm, 15 μΩcm, 20 μΩcm, 50 μΩcm, 100 μΩcm, 150 μΩcm or 200 μΩcm. The thickness of a layer with said resistivity may be, for example, 10 nm, 20 nm, 30 nm, 40 nm, 50 nm or 60 nm.

Resistivity of a molybdenum layer may be reduced by using a post-deposition anneal. Annealing may be performed directly after depositing of a molybdenum layer, i.e. without additional layers being deposited. Alternatively, annealing may be performed after additional layers have been deposited. Molybdenum layer may be capped before annealing. A capping layer may comprise, consist essentially of, or consist of silicon nitride. An annealing temperature from about 320° C. to about 470° C. could be used. For example, an annealing temperature may be 330° C., 350° C., 380° C., 400° C., 430° C. or 450° C. Annealing may be performed in a gas atmosphere comprising, consist essentially of, or consist of argon, argon-hydrogen mixture, hydrogen, nitrogen or nitrogen-hydrogen mixture. Duration of annealing may be from about 1 minute to about 60 minutes, for example 5 minutes, 20 minutes, 30 minutes or 45 minutes. An annealing may be performed at a pressure of 0.05 to 760 Torr. For example, a pressure during annealing may be about 1 Torr, about 10 Torr, about 100 Torr or about 500 Torr.

FIG. 1C depicts an embodiment of the current disclosure similar to that of FIG. 1B, in which the method comprises deposition cycles of different configurations. The method is started by providing a substrate into the reaction chamber 102 as above. The stages of the first configuration (an “initiator cycles”), 104a to 107a, may be performed as described above, but the pulse time at providing reactant into the reaction chamber 106a may be extended. The length of a reactant pulse in the initiator cycle is selected to improve the rate of deposition in the following deposition cycles. In some embodiments, the reactant pulse time at stage 106a is at least 3 seconds, or between about 3 seconds and about 60 seconds, for example, about 5 seconds, about 10 seconds, about 15 seconds, about 30 seconds or about 45 seconds. The initiator cycle may be repeated (loop 108a). In some embodiments, the initiator cycle is performed at least about 5 times, for example about 10 times, about 20 times, about 25 times or about 30 times. In some embodiments, the reactant pulse 106a has a duration of about 10 seconds, and the initiator cycle is performed about 20 times. After the initiator cycle has been performed sufficiently many times for the application in question, stages 104 to 107 are performed as above, and repeated 108. However, in some embodiments, the number of deposition cycles needed to achieve a target molybdenum layer thickness may be reduced by at least 10%, or by at least 50% or by at least 60% by the use of an initiator cycle. For comparison, the reactant pulse time in the deposition cycles 108 following the initiator cycles 108a may be shorter than about 3 seconds, for example about 1 second or about 2 seconds. Thus, in some embodiments, the method according to the current disclosure comprises reactant pulses of two different lengths.

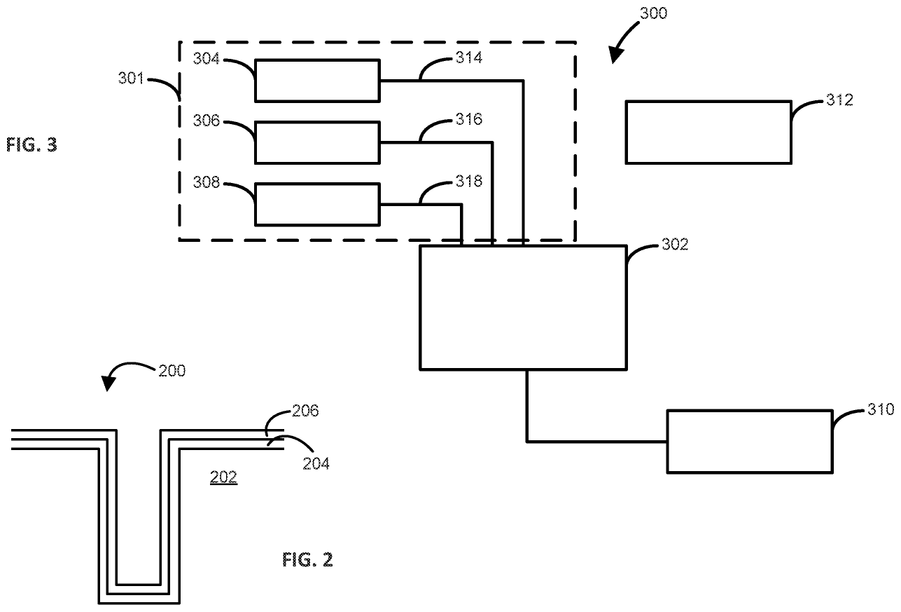

FIG. 2 illustrates an exemplary structure, or a portion of a device 200 in accordance with the disclosure. Portion of a device or structure 200 includes a substrate 202, a molybdenum layer 204, and an optional underlayer 206 in between (e.g., in contact with one or both) substrate 202 and molybdenum layer 204. Substrate 202 can be or include any of the substrate material described herein, such as a dielectric or insulating layer. By way of example, dielectric or insulating layer can be high-k material, such as, for example, a metallic oxide. In some embodiments, the high-k material has a dielectric constant higher than the dielectric constant of silicon oxide. Exemplary high-k materials include one or more of hafnium oxide (HfO₂), tantalum oxide (Ta₂O₅), zirconium oxide (ZrO₂), titanium oxide (TiO₂), hafnium silicate (HfSiOx), aluminum oxide (Al₂O₃), lanthanum oxide (La₂O₃), titanium nitride, and mixtures/laminates comprising one or more such layers. Alternatively, substrate material may comprise metal.

Molybdenum layer 204 can be formed according to a method described herein. In embodiments, in which an underlayer 206 is formed, the underlayer may be formed using a cyclical deposition process. In some embodiments, molybdenum layer 204 can be molybdenum metal. In some embodiments, a molybdenum layer may be deposited directly on the substrate. In such embodiments, there is no underlayer. As a further alternative, the structure or a device according to the current disclosure may comprise additional layers between substrate and molybdenum layer.

FIG. 3 illustrates a deposition assembly 300 according to the current disclosure in a schematic manner. Deposition assembly 300 can be used to perform a method as described herein and/or to form a structure or a device, or a portion thereof as described herein.

In the illustrated example, deposition assembly 300 includes one or more reaction chambers 302, a precursor injector system 301, a molybdenum precursor vessel 304, reactant vessel 306, a purge gas source 308, an exhaust source 310, and a controller 312.

Reaction chamber 302 can include any suitable reaction chamber, such as an ALD or CVD reaction chamber.

The molybdenum precursor vessel 304 can include a vessel and one or more molybdenum precursors as described herein—alone or mixed with one or more carrier (e.g., inert) gases. Reactant vessel 306 can include a vessel and one or more reactants as described herein—alone or mixed with one or more carrier gases. Purge gas source 308 can include one or more inert gases as described herein. Although illustrated with three source vessels 304-308, deposition assembly 300 can include any suitable number of source vessels. Source vessels 304-308 can be coupled to reaction chamber 302 via lines 314-318, which can each include flow controllers, valves, heaters, and the like. In some embodiments, the molybdenum precursor in the precursor vessel may be heated. In some embodiments, the vessel is heated so that the molybdenum precursor reaches a temperature between about 60° C. and about 160° C., such as between about 100° C. and about 145° C., for example 85° C., 100° C., 110° C., 120° C., 130° C. or 140° C.

Exhaust source 310 can include one or more vacuum pumps.

Controller 312 includes electronic circuitry and software to selectively operate valves, manifolds, heaters, pumps and other components included in the deposition assembly 300. Such circuitry and components operate to introduce precursors, reactants and purge gases from the respective sources 304-308. Controller 312 can control timing of gas pulse sequences, temperature of the substrate and/or reaction chamber 302, pressure within the reaction chamber 302, and various other operations to provide proper operation of the deposition assembly 300. Controller 312 can include control software to electrically or pneumatically control valves to control flow of precursors, reactants and purge gases into and out of the reaction chamber 302. Controller 312 can include modules such as a software or hardware component, which performs certain tasks. A module may be configured to reside on the addressable storage medium of the control system and be configured to execute one or more processes.

Other configurations of deposition assembly 300 are possible, including different numbers and kinds of precursor and reactant sources and purge gas sources. Further, it will be appreciated that there are many arrangements of valves, conduits, precursor sources, and purge gas sources that may be used to accomplish the goal of selectively and in coordinated manner feeding gases into reaction chamber 302. Further, as a schematic representation of an deposition assembly, many components have been omitted for simplicity of illustration, and such components may include, for example, various valves, manifolds, purifiers, heaters, containers, vents, and/or bypasses.

During operation of deposition assembly 300, substrates, such as semiconductor wafers (not illustrated), are transferred from, e.g., a substrate handling system to reaction chamber 302. Once substrate(s) are transferred to reaction chamber 302, one or more gases from gas sources 304-308, such as precursors, reactants, carrier gases, and/or purge gases, are introduced into reaction chamber 302.

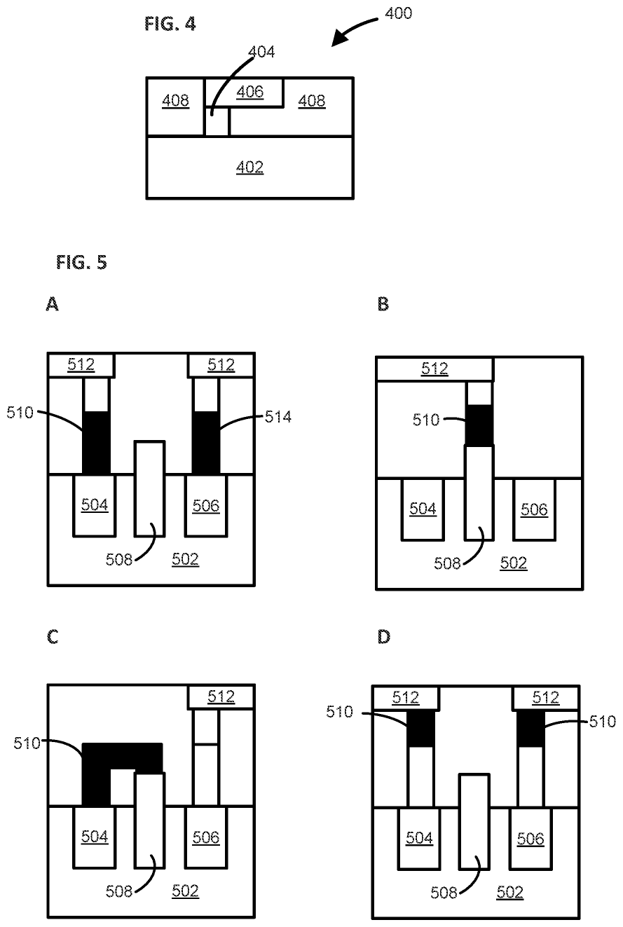

FIG. 4 illustrates a line 406 and a via 404 in a semiconductor device 400. The device is positioned on a semiconductor substrate 402. The substrate may contain any of the substrate material described in the current disclosure. Additional functional layers (not depicted in the figure) may be present on the substrate 402. A via 404 is in contact with the substrate and a line 406. The via 404 may comprise, consist essentially of, or consist of molybdenum deposited according to the current disclosure. The line 406 may comprise consist essentially of, or consist of molybdenum deposited according to the current disclosure, or it may comprise, consist essentially of, or consist of another metal such as copper. The via 404 and the line 406 are surrounded by low k material.

FIG. 5, panels A to D, exemplifies molybdenum deposited according to the current disclosure in different contact applications. In all panels, substrate is indicated with the numeral 502, source with numeral 504, drain with numeral 506, gate with numeral 508 and a contact with numeral 512. In panel A, molybdenum deposited according to the current disclosure is used in a source contact 510 and a drain contact 514. In panel B, molybdenum deposited according to the current disclosure is used in a gate contact 510 and in panel C, in a local interconnect 510 between a gate 508 and a source 504. In panel D, molybdenum is used in a connect 510 between a via and a contact 512.

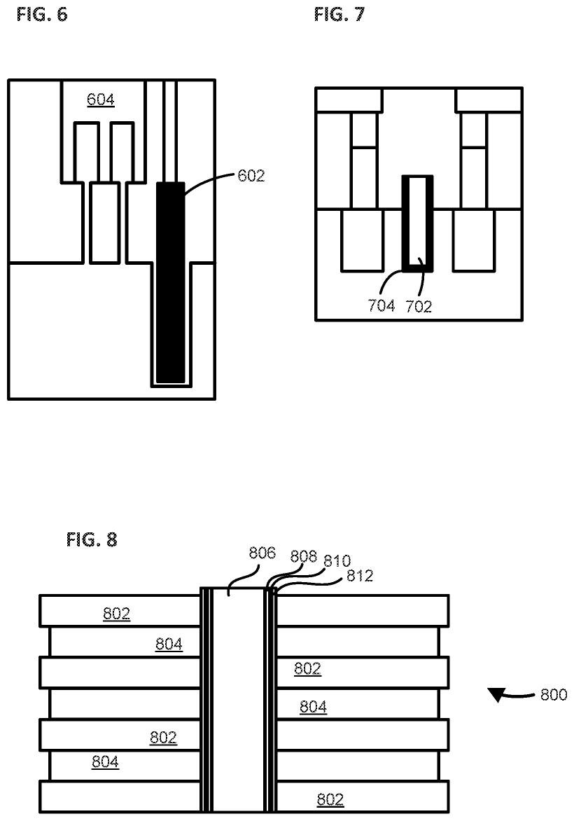

FIG. 6 depicts buried power rail 602 comprising molybdenum deposited according to the current disclosure, and a FinFET structure 604.

FIG. 7 illustrates a gate 702, in which a work function layer 704 comprises, consist essentially of, or consist of molybdenum deposited according to the current disclosure in similar device as depicted in FIG. 5.

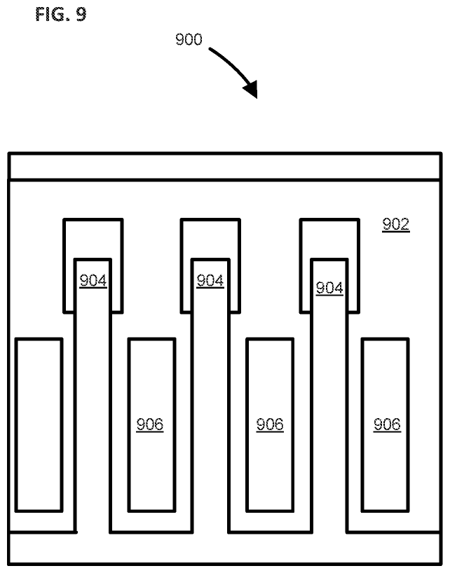

FIG. 8 is an illustration of a 3D NAND 800 in which word line 804 comprises, consist essentially of, or consist of molybdenum deposited according to the current disclosure. The figure displays exemplary embodiments of channel 806, tunnel oxide 808, a charge trap layer 810 and a blocking oxide 812 for reference.

FIG. 9 illustrates an exemplary embodiment of a DRAM 900 with buried word line 906. In the figure, 902 indicates source, 904 gate, 910 a bitline. Buried word line 906 comprises, consist essentially of, or consist of molybdenum deposited according to the current disclosure.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Various modifications of the disclosure, in addition to those shown and described herein, such as alternative useful combinations of the elements described, may become apparent to those skilled in the art from the description. Such modifications and embodiments are also intended to fall within the scope of the appended claims.

1. A method of depositing molybdenum on a substrate by a cyclical deposition process, the method comprising
providing a substrate in a reaction chamber;
providing a molybdenum precursor to the reaction chamber in a vapor phase; and
providing a reactant to the reaction chamber in a vapor phase to form molybdenum on the substrate; wherein
the molybdenum precursor comprises a molybdenum atom and hydrocarbon ligand, and the reactant comprises a halogenated hydrocarbon comprising two or more halogen atoms, at least two halogen atoms being attached to different carbon atoms.

2. The method of claim 1, wherein the molybdenum precursor comprises an organometallic compound comprising only molybdenum, carbon and hydrogen.

3. The method of claim 2, wherein the molybdenum precursor comprises bis(ethylbenzene)molybdenum.

4. The method of claim 1, wherein the two halogen atoms in the reactant are attached to adjacent carbon atoms of the hydrocarbon.

5. The method of claim 1, wherein the reactant comprises a 1,2-dihaloalkane or 1,2-dihaloalkene or 1,2-dihaloalkyne or 1,2-dihaloarene

6. The method of claim 1, wherein the reactant has a general formula XₐR_{b}C—(CX_{c}R″ₐ)ₙ—CXₐR′_{b}, wherein X is halogen, R, R′ and R″ are independently H or an alkyl group, a and b are independently 1 or 2, so that for each carbon atom a+b=3, n is 0, 1, 2, 3, 4 or 5, and c and d are independently 0, 1 or 2, so that for each carbon atom c+d=2.

7. The method of claim 1, wherein the reactant has a general formula XₐR_{b}C—CXₐR′_{b}, wherein X is halogen, R and R′ are independently H or an alkyl group, a and b are independently 1 or 2, so that for each carbon atom a+b=3.

8. The method of claim 1, wherein the two halogen atoms of the reactant are the same halogen.

9. The method of claim 1, wherein the two halogen atoms of the reactant are iodine.

10. The method of claim 1, wherein the reactant comprises 1,2-diiodoethane.

11. The method of claim 1, wherein the molybdenum precursor is supplied in pulses, reactant supplied in pulses and the reaction chamber is purged between consecutive pulses of molybdenum precursor and reactant.

12. The method of claim 1, wherein the method comprises reactant pulses of two different lengths.

13. The method of claim 1, wherein the pressure in the reaction chamber is between 0.1 and 100 Torr.

14. The method of claim 1, wherein the process temperature is between about 200° C. and 400° C.

15. The method of claim 1, wherein the cyclical deposition process comprises an atomic layer deposition process or a chemical vapor deposition process.

16. The method of claim 1, wherein the cyclical deposition process comprises a thermal deposition process.

17. A molybdenum layer produced of the method of claim 1.

18. The layer of claim 17 having a resistivity of from about 15 μΩcm to about 300 μΩcm, such as 20 μΩcm, 50 μΩcm, 100 μΩcm, 150 μΩcm or 200 μΩcm.

19. A semiconductor structure comprising molybdenum deposited of claim 1.

20. A semiconductor device comprising molybdenum deposited of claim 1.

21. A deposition assembly for depositing molybdenum on a substrate comprising:
one or more reaction chambers constructed and arranged to hold the substrate;
a precursor injector system constructed and arranged to provide a molybdenum precursor and/or a reactant into the reaction chamber in a vapor phase;
wherein the deposition assembly comprises a precursor vessel constructed and arranged to contain and evaporate a molybdenum precursor comprising a molybdenum atom and a hydrocarbon ligand; and
a reactant vessel constructed and arranged to contain and evaporate a reactant comprising a halogenated hydrocarbon comprising two or more halogen atoms, at least two halogen atoms being attached to different carbon atoms; and
the assembly is constructed and arranged to provide the molybdenum precursor and/or the reactant via the precursor injector system to the reaction chamber to deposit molybdenum on the substrate.
